(19) United States
(12) Patent Application Publication
(10) Pub. No.: US 2026/0181966 A1
(43) Pub. Date: Jun. 25, 2026

(54) METHOD FOR MANUFACTURING A FeMFET DEVICE

(71) Applicant: COMMISSARIAT A L'ENERGIE ATOMIQUE ET AUX ENERGIES ALTERNATIVES, Paris (FR)

(72) Inventors: Thibaut CHÊNE, Grenoble Cedex 09 (FR); Fabrice NEMOUCHI, Grenoble Cedex 09 (FR); Roselyne SEGAUD, Grenoble Cedex 09 (FR); Christelle BOIXADERAS, Grenoble Cedex 09 (FR); Thierry CHEVOLLEAU, Grenoble Cedex 09 (FR); Laurent GRENOUILLET, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/422,686

(22) Filed: Dec. 17, 2025

(30) Foreign Application Priority Data
Dec. 20, 2024 (FR) FR2414888

(51) Int. Cl. H10D 30/69; H10D 1/66; H10D 64/68

(52) U.S. Cl. CPC H10D 30/701; H10D 1/66; H10D 64/689

(57) ABSTRACT

A method for manufacturing an FeMFET device may include: a providing a transistor including a gate, a source, and a drain connected to vias; forming a first metal layer; forming a ferroelectric layer; structuring the ferroelectric layer to form a closed pattern surmounting the gate and open patterns surmounting the vias; forming a second metal layer; etching the second metal layer, configured to form vias by stopping on the ferroelectric layer; and etching the first metal layer on either side of the closed pattern and of the open patterns, configured to form lines.

### TECHNICAL FIELD

The present invention relates to the technical field of memory devices for microelectronics. It has a particularly advantageous application in the formation of ferroelectric memory devices integrated in back end of line levels of a microelectronic chip.

### PRIOR ART

The ferroelectric properties of the HfO₂ or HfₓZr₁₋ₓO₂ (H₂O) material deposited in thin layers are particularly interesting for the integration of non-volatile memories in so-called “back end of line” (“BEOL”) levels of CMOS (Complementary Metal-Oxide-Semiconductor) technology for the most advanced technological nodes. Ferroelectric HfO₂-based memories of the FeRAM (Ferroelectric Random Access Memory) type are currently developed for non-volatile applications, with the aim of replacing Flash-type memories. They, in particular, have the advantage of having a very low energy consumption. The basic cell of an FeRAM memory comprises, in particular, a ferroelectric capacitor, in which information is stored in the form of the polarisation state of the electric dipoles. By connecting the HfO₂ ferroelectric capacitor to the gate of a field-effect transistor, a device commonly called FeMET (Ferroelectric Metal Field Effect Transistor) can also be formed. This type of FeMET “ferroelectric transistor” advantageously has a variable threshold voltage according to the polarisation state of the ferroelectric capacitor. The information density stored in such a device can be increased. Such an FeMET device also makes it possible to consider “in-memory” computing, making it possible to decrease the energy consumption of electronic systems.

A known solution for integrating this type of device in “back end” levels consists of first forming ferroelectric capacitors on CMOS transistor gates, through a dedicated lithography mask. The interconnecting vias are then formed conventionally, for example, according to a so-called “damascene” approach. This increases the number of steps and the cost of the method. In particular, there is a need aiming to optimise the method for producing FeMFET devices at least partially integrated in the “back end”.

An aim of the present invention is to respond to this need, by totally or partially overcoming the disadvantages mentioned above.

In particular, an aim of the present invention is to propose a method for forming a FeMFET device having a reduced cost. Another aim of the present invention is to propose a method for forming a FeMFET device which has a limited number of steps.

### SUMMARY

To achieve this aim, according to an embodiment, a FeMFET device is provided, comprising, in a stack along a direction z:
a transistor comprising a gate surmounting a channel, a source and a drain on either side of the channel,
at least one interconnection connecting the source or the drain, comprising:
   at least one metal line with the basis of a first metal, and,
   at least one metal via with the basis of a second metal, connected to said at least one metal line,
   an etching stop layer inserted between the at least one via and the at least one line, said etching stop layer comprising at least one via opening, such that the at least one via and the at least one line are connected through said at least one via opening,
a ferroelectric capacitor connecting the gate, comprising:
   at last one metal line with the basis of the first metal, and,
   at least one metal via with the basis of the second metal,
   a first part of a ferroelectric layer inserted between the at least one via and the at least one line, said ferroelectric layer separating the at least one via and the at least one line.

An FeMFET device at least partially integrated in the “back end”, connected by interconnections, is advantageously produced. The formation of the interconnections and of the ferroelectric capacitor can advantageously be done during the same etching steps.

The invention also provides steps of producing such an FeMFET device.

The advantages described above regarding the device apply mutatis mutandis to the methods according to the invention.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1A to 13A schematically illustrate a cross-section, in a plane xz, different steps of the method for manufacturing an FeMFET device according to a first embodiment of the present invention.

FIGS. 1B to 13B schematically illustrate, in perspective, the steps of the method for manufacturing an FeMFET device illustrated respectively in FIGS. 1A to 13A, according to the first embodiment of the present invention.

FIGS. 14A to 24A schematically illustrated, in a cross-section, in a plane xz, different steps of the method for manufacturing an FeMFET device according to a second embodiment of the present invention.

FIGS. 14B to 24B schematically illustrate, in perspective, the steps of the method for manufacturing an FeMFET device illustrated respectively in FIGS. 14A to 24A, according to the second embodiment of the present invention.

The drawings are given as examples and are not limiting of the invention. They constitute principle schematic representations, intended to facilitate the understanding of the invention, and are not necessarily to the scale of practical applications. In particular, the thicknesses and/or the dimensions of the different layers and patterns are not representative of reality.

### DETAILED DESCRIPTION

Before starting a detailed review of embodiments of the invention, optional features are stated below, which can optionally be used in association or alternatively:

According to an example, the etching stop layer has, with respect to the first metal layer, a selectivity S_{21:30b} to the etching, greater than or equal to 5:1.

According to an example, the ferroelectric layer has a selectivity to the etching S_{21:31}, greater than or equal to 5:1 with respect to the first metal.

According to an example, the etching stop layer inserted between the at least one via and the at least one line of the at least one interconnection is ferroelectric. The etching stop layer inserted between the at least one via and the at least one line of the at least one interconnection typically corresponds to a second part of the ferroelectric layer. The ferroelectric layer is used, in this case, both as an etching stop layer and as a functional layer for the ferroelectric capacitor. This limits the number and the nature of the layers in the device. The manufacturing cost of the device is decreased.

According to an example, the at least one interconnection comprises a first interconnection connecting the source and a second interconnection connecting the drain, and each of the first and second interconnections comprises an etching stop layer inserted between the at least one via and the at least one line of said interconnection. All the interconnections of the device typically have an etching stop layer part inserted between two successive metal levels of said interconnections. In this example, the etching stop layer can be ferroelectric or non-ferroelectric.

According to an example, the vias connecting the source and the drain of the transistor are obtained according to a “damascene” approach. After formation of the gate and of the source and drain of the transistor, a dielectric layer is deposited on the source and drain. This dielectric layer is typically planarised, so as to expose an upper face of the gate. Openings, opening onto the source and drain of the transistor are formed within the dielectric layer, then filled by a metal. A planarisation is done, so as to remove the metal on the surface of the dielectric layer and of the upper face of the gate. Vias connecting the source and drain, and having coplanar exposed faces with the upper face of the gate, are thus obtained. The upper surface of the transistor provided, comprising the exposed faces of the vias and of the gate, is advantageously flat. This facilitates subsequent depositions, in particular the deposition of the first metal layer and/or the deposition of the ferroelectric layer.

According to an example, the ferroelectric layer has a thickness e₃₀ₐ of between 2 nm and 15 nm, preferably between 7 nm and 10 nm.

According to an example, the ferroelectric layer is with the basis of a material taken from among: HfₓZr₁₋ₓO₂, HfO₂. The HfO₂ material can be non-doped or doped. According to an example, the HfO₂ material is doped by at least one from among the following elements: Si, N, Gd, Y, Sc, Ge. The concentration of doping elements is typically between 0% and 10% at., preferably between 0.5% and 3% at.

According to an example, the structuration of the ferroelectric layer comprises the following substeps:
a formation of the first mask on the ferroelectric layer, said first mask directly defining the at least one closed pattern and the at least one open pattern comprising the at least one via opening,
a partial removal of the ferroelectric layer, only at the zones of the ferroelectric layer not covered by the first mask, so as to expose the first metal layer outside of the zones covered by the first mask,
a removal of the first mask.

In this example, the parts covered by the first mask correspond to the open and closed patterns. The lower electrode of the ferroelectric capacitor and the lines of the first level contributing to the source and drain interconnections are defined, thanks to only the first mask.

According to an example, the partial removal of the ferroelectric layer is done by etching with the basis of a chlorinated chemistry BCl₃.

According to an example, the formation of the first mask is done by double lithography. This known lithography method makes it possible to optimise, even exceed the resolution limitations of a conventional item of lithography insolation equipment. Another solution consists of using a better resolved item of lithography equipment, for example, in extreme UV or in electron lithography. The formation of the first mask can comprise a first lithography, followed by a second lithography, then an etching. Alternatively, the formation of the first mask can comprise a first lithography, followed by a first etching, then a second lithography, followed by a second etching.

According to an example, the first mask is with the basis of a non-metal material, for example, SiON-, SiN-, SiCN-, HfO₂-, SION-, SiC-based.

According to an example, the via(s) of the second level surmounting the closed pattern(s) have a critical dimension CDᵥᵢₐ₂₂₁, taken along an axis x, less than a dimension CD₁, taken along the axis x, of the closed pattern(s). This makes it possible to minimise the risk linked to a misalignment between the first and second masks. The lines of the first level being typically wider than the vias of the second level, the etching of the second metal layer, associated with the formation of the vias of the second level, will actually stop on the ferroelectric layer, structured along the closed pattern(s). The reliability of the method is increased.

According to an example, the via(s) of the second level surmounting the open pattern(s) have a critical dimension CDᵥᵢₐ₂₀, taken along an axis x, greater than or equal to a dimension CDₒₚₑₙ of the at least one via opening taken along the axis x. This makes it possible to minimise the risk linked to a misalignment between the first and second masks. The vias of the second level being typically wider than the via openings, the alignment of the second mask defining the vias in vertical alignment with the via openings is facilitated. The etching of the second metal layer, during the formation of the vias of the second level, will actually stop on the ferroelectric layer, structured along the open pattern(s). The etching of the second metal layer does not extend to the via openings. The reliability of the method is increased.

According to an example, the first and second metal layers are with the basis of one same metal material, for example, TaN, TIN, Al, Ru, Mo.

According to an example, the etching of the second metal layer and the etching of the first metal layer are done by one single and same etching, during one single and same step.

According to an example, the first and second metal layers are respectively with the basis of a first metal material and of a second metal material, said first and second metal materials being different from one another.

According to an example, the etching of the second metal layer and the etching of the first metal layer are done by two different successive etchings.

According to an example, a method for manufacturing an FeMFET device, comprising:
a provision of a transistor comprising a gate surmounting a channel, a source and a drain on either side of the channel, and vias connecting the source and the drain, said vias and said gate each having an exposed face at an upper surface,
a formation of a first metal layer on the exposed faces of the upper surface,
a formation, on the first metal layer, of a ferroelectric layer with the basis of a ferroelectric material having, with respect to the first metal layer, a selectivity S_{21:30a} to the etching, greater than or equal to 5:1,
a structuration of the ferroelectric layer, through at least one first mask, so as to expose parts of the first metal layer and to preserve parts of the ferroelectric layer in the form of at least one closed pattern surmounting the gate of the transistor and at least one open pattern surmounting at least one of the vias connecting the source or the drain, said at least one open pattern comprising at least one via opening, opening onto the first underlying metal layer,
a formation of a second metal layer on the exposed parts of the first metal layer, and on the at least one closed pattern and the at least one open pattern,
a formation, on the second metal layer, of a second mask defining at least one second via level in vertical alignment with the at least one closed pattern and in vertical alignment with the at least one via opening of the at least one open pattern,
an etching of the second metal layer, said etching being configured to form the vias of the second level by stopping on the ferroelectric layer, and,
an etching of the first metal layer on either said of the at least one closed pattern and the at least one open pattern, said etching being configured to form first-level lines by stopping on the upper surface.

The vias of the second level surmounting the open patterns are connected to the lines of the first level through the at least one via openings. These lines of the first level are themselves connected to the vias connecting the source and the drain of the transistor. Interconnections to the source and the drain of the transistor are thus formed through several metal levels.

In this example, the vias of the second level surmounting the closed patterns are separated from the lines of the first level by the ferroelectric material. A ferroelectric capacitor is thus formed between several metal levels. The lower electrode of the ferroelectric capacitor and the lines of the first level contributing to the source and drain interconnections are formed from the first metal layer.

An FeMFET device at least partially integrated in the “back end”, connected by interconnections, is advantageously produced. The formations of the interconnections and of the ferroelectric capacitor are done advantageously during the same etching steps.

This method resorts to a ferroelectric layer, structured and buried between the first and second metal layers. This ferroelectric layer, which has a selectivity S_{21:30a} to the etching, greater than or equal to 5:1, advantageously acts as an etching stop layer. Such an etching stop interlayer advantageously makes it possible to perform the etching(s) of the metal layers successively, for example, in one single step or in a sequenced manner. The number of steps of the method is thus limited.

According to another example, a method for manufacturing an FeMFET device is provided, comprising:
a provision of a transistor comprising a gate surmounting a channel, a source and a drain on either side of the channel, and vias connecting the source and the drain, said vias and said gate each having an exposed face at an upper surface,
a formation of a first metal layer on the exposed faces of the upper surface,
a formation, on the first metal layer, of an etching stop layer,
a structuration of the etching stop layer, through at least one first mask, so as to expose parts of the first metal layer, and to preserve parts of the etching stop layer in the form of at least one open pattern surmounting the gate, and at least one of the vias connecting the source or the drain, said at least one open pattern comprising at least one via opening, opening onto the first underlying metal layer,
a formation of a second metal layer on the exposed parts of the first metal layer, and on the at least one open pattern,
a formation, on the second metal layer, of a ferroelectric layer with the basis of a ferroelectric material having, with respect to the second metal layer, a selectivity S_{22:30a} to the etching, greater than or equal to 5:1,
a structuration of the ferroelectric layer, through at least one second mask, so as to expose parts of the second metal layer, and to preserve parts of the ferroelectric layer in the form of at least one closed pattern surmounting the gate of the transistor,
a formation of a third metal layer on the exposed parts of the second metal layer and on the at least one closed pattern,
a formation, on the third metal layer, of a third mask defining vias in vertical alignment with the at least one closed pattern and in vertical alignment with the at least one via opening of the at least one open pattern,
at least one etching of the third, second and first metal layers, said at least one etching being configured to form the vias, by stopping on the ferroelectric layer and on the etching stop layer, and to form lines by stopping on the upper surface.

In this example, the lower electrode of the ferroelectric capacitor is formed from first and second metal layers. The lines of the first level contributing to the source and drain interconnections are formed from the first metal layer.

In this example, the ferroelectric capacitor is formed within upper interconnecting levels. It can be relatively away from the transistor to which it is associated. The ferroelectric layer only forms the closed pattern. The underlying etching stop layer forms an open pattern. This makes it possible to consider different combinations of closed and open patterns. The sizing of the lower electrode of the capacitor and/or of the ferroelectric layer for separating the capacitor is better controlled. The etching selectivity between the different metal layers and the dielectric layer can be adjusted, for example, reduced.

Unless incompatible, it is understood that all of the optional features above and/or the variants indicated can be combined, so as to form an embodiment which is not necessarily illustrated or described. Such an embodiment is clearly not excluded from the invention.

It is specified that, in the scope of the present invention, the terms “on”, “surmounts”, “covers”, “underlying”, “opposite” and their equivalents do not necessarily mean “in contact with”. Thus, for example, the deposition or the application of a first layer on a second layer, does not compulsorily mean that the two layers are directly in contact with one another, but means that the first layer at least partially covers the second layer, by being either directly in contact with it, or by being separated from it by at least one other element.

By a substrate, a film, a layer “with the basis” of a material A, this means a substrate, a film, a layer comprising this material A only, or this material A and optionally other materials, for example, doping elements or alloy elements. Thus, a silicon nitride SiN-based etching stop layer can, for example, comprise non-stoichiometric silicon nitride (SiN), or stoichiometric silicon nitride (Si₃N₄), or also a silicon oxynitride (SION).

By closed pattern, this means a pattern which does not communicate with the underlying layer. On the contrary, by open pattern, this means a pattern which communicates with the underlying layer through an opening, typically through a via opening.

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time, and in the sequence of the phases of the method. The etchings of the first and second metal layers can, in particular, be sequenced or be considered as forming part of one single and same etching step.

By “selective etching with respect to” or “etching having a selectivity with respect to”, this means an etching configured to remove a material A or a layer A with respect to a material B or a layer B, and having an etching speed of the material A, greater than the etching speed of the material B. The selectivity is the ratio between the etching speed of the material A over the etching speed of the material B. It is referenced SAB. A selectivity S_{A:B} of 10:1 means that the etching speed of the material A is 10 times greater than the etching speed of the material B.

A preferably orthonormal system, comprising the axes x, y, z is represented in the accompanying figures.

In the present patent application, thickness will preferably be referred to for a layer or a film, and height will preferably be referred to for a device or a structure. The thickness is taken along a direction normal to the main extension plane of the layer or of the film. Thus, a metal layer typically has a thickness along z. A via formed from such a metal layer has a height along z. The relative terms “on”, “surmounts”, “upper”, “under”, “underlying”, “lower” refer to positions taken along the direction z. A “lateral” dimension corresponds to a dimension along a direction of the plane xy. By a “lateral” extension or “laterally”, this means an extension along one or more directions of the plane xy.

An element located “in vertical alignment with” or “to the right of” another element, means that these two elements are both located on one same line, perpendicular to a plane in which a lower or upper face of a substrate mainly extends, i.e. on one same line oriented vertically in the figures, in a cross-section.

The terms “substantially”, “around”, “about” mean plus or minus 10%, preferably plus or minus 5%. Moreover, the term “between . . . and . . . ” and equivalents, this means that the limits are inclusive, unless mentioned otherwise.

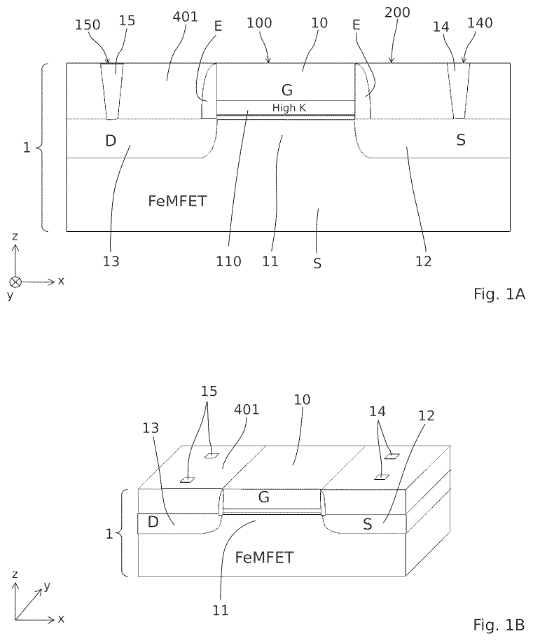

Steps of manufacturing an FeMFET device according to a first embodiment of the invention are illustrated in FIGS. 1A, 1B to 13A, 13B.

As illustrated in FIGS. 1A, 1B, the method comprises a provision of a transistor 1, for example MOS (metal-oxide-semiconductor) type. This transistor 1 typically comprises a silicon-based substrate S, a gate 10 surmounting the substrate S, a source 12 and a drain 13 on either side of the gate 10, for example, within the substrate S, and a channel 11 under the gate 10 and separated from the gate 10 by one or more dielectric layers 110. The gate 10 is typically flanked by spacers E.

The transistor 1 also comprises, in this case, the vias 14, 15 respectively connecting the source 12 and the drain 13 of the transistor. These vias 14, 15 are preferably obtained according to a “damascene” approach. According to this approach, after formation of the gate 10 and of the source 12 and drain 13 of the transistor, a dielectric layer 401 is deposited. This dielectric layer 401 is typically planarised by chemical-mechanical polishing CMP, so as to expose an upper face 100 of the gate 10. Openings, opening onto the source 12 and drain 13 of the transistor are formed within the dielectric layer 401, then filled by a metal. A planarisation, for example, by CMP, is done, so as to remove the metal on the surface of the dielectric layer 401 and from the upper face of the gate 10. The vias 14, 15 are thus obtained. They respectively have exposed faces 140, 150, coplanar with the upper face 100 of the gate 10. The upper surface 200 of this transistor 1, comprising the exposed faces 140, 150, 100, is advantageously flat.

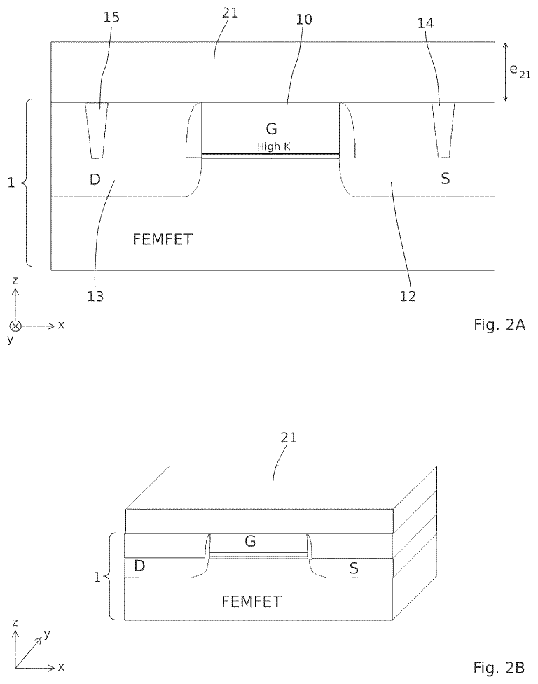

As illustrated in FIGS. 2A, 2B, a first metal layer 21, typically with the basis of a metal taken from among TaN, TIN, Al, Ru, Mo, is first formed on the surface 200 of the transistor 1. The vias 14, 15 and the gate 10 are directly in contact with the metal layer 21. This metal layer 21 typically has a thickness e₂₁ of around a few tens of nanometres to few hundreds of nanometres, for example, between 20 nm and 200 nm. The deposition of this metal layer 21 can, in particular, be done by one of the following techniques: physical vapour deposition (PVD), chemical vapour deposition (CVD), atomic layer deposition (ALD). After deposition, the first metal layer 21 can be planarised, for example, by CMP. The first metal layer 21 typically corresponds to a first metal level.

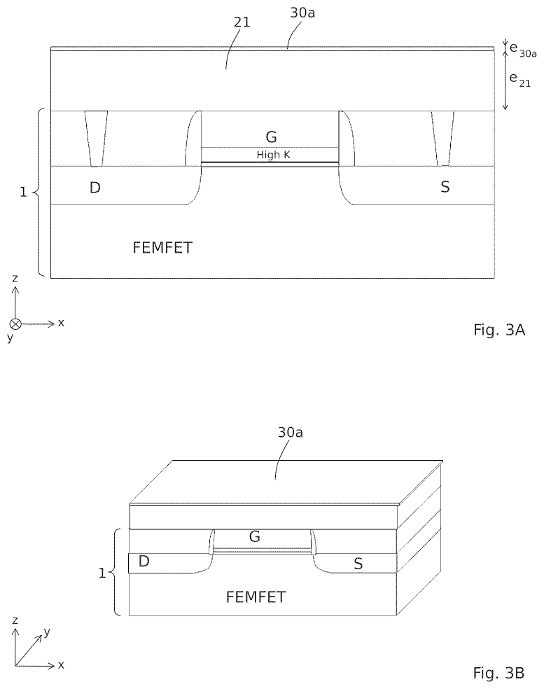

As illustrated in FIGS. 3A, 3B, a ferroelectric layer 30a is then directly formed on the first metal layer 21. This ferroelectric layer 30a typically has a thickness e₃₀ₐ of around a few nanometres, for example, between 2 nm and 15 nm. It is preferably with the basis of a material taken from among: HfₓZr₁₋ₓO₂, HfO₂. The deposition of this ferroelectric layer 30a is preferably done by ALD.

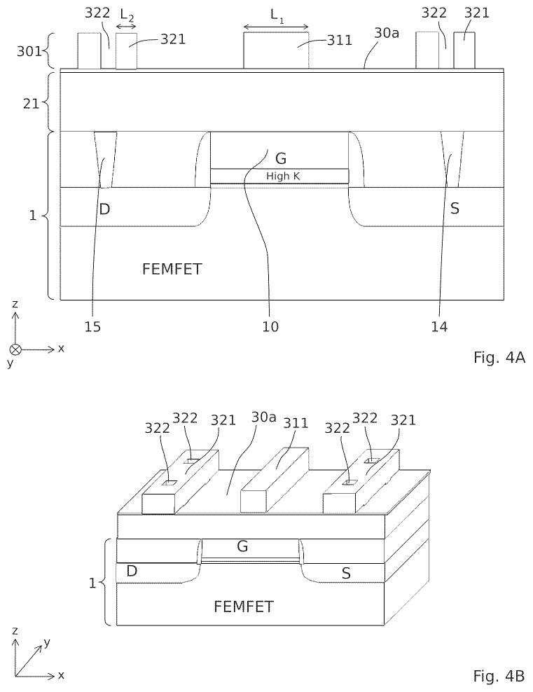

As illustrated in FIGS. 4A, 4B, an etching mask 301 is formed on the ferroelectric layer 30a. This etching mask 301 is, for example, SiON-based. It is typically obtained by lithography/etching, for example, through a single lithography in extreme UV insolation, or through a double lithography, also called “double patterning”.

The etching mask 301 comprises a solid pattern 311 above the gate 10 of the transistor 1, and open patterns 321 above the vias 14, 15. The open patterns 321 comprise one or more openings 322, opening onto the underlying ferroelectric layer 30a. The solid pattern 311 typically has a dimension L₁ along x of between 20 nm and 300 nm, according to the lithography technique implemented. The open patterns 321 typically have a dimension L₂ along x of between 8 nm and 150 nm, according to the lithography technique implemented.

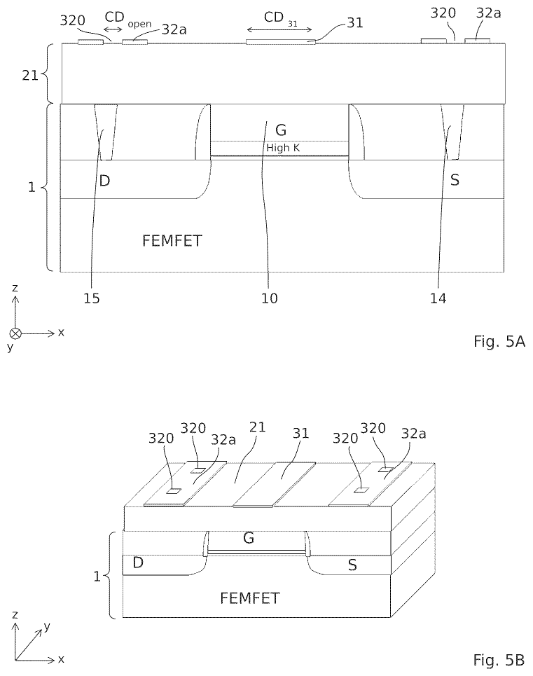

As illustrated in FIGS. 5A, 5B, the patterns 311, 321 are transferred into the ferroelectric layer 30a by anisotropic etching along z of the ferroelectric layer 30a, in the presence of the mask 301. The etching of the ferroelectric layer 30a can be done by plasma with the basis of a chlorinated etching chemistry, for example, BCl, BCl₃. The solid pattern 311 of the mask 301 forms, after etching, the closed pattern 31 in the ferroelectric layer 30a. The open patterns 321 of the mask 301 form, after etching, the open patterns 32a comprising the via openings 320 in the ferroelectric layer 30a. The patterns 31, 32a substantially have the same dimensions as the patterns 311, 321. The closed pattern 31 typically has the dimension CD₃₁ along x, and the via openings 320 of the open patterns 32a typically have the dimension CDₒₚₑₙ along x. The mask 301 is removed after etching, for example, by oxygen- or hydrogen-based plasma.

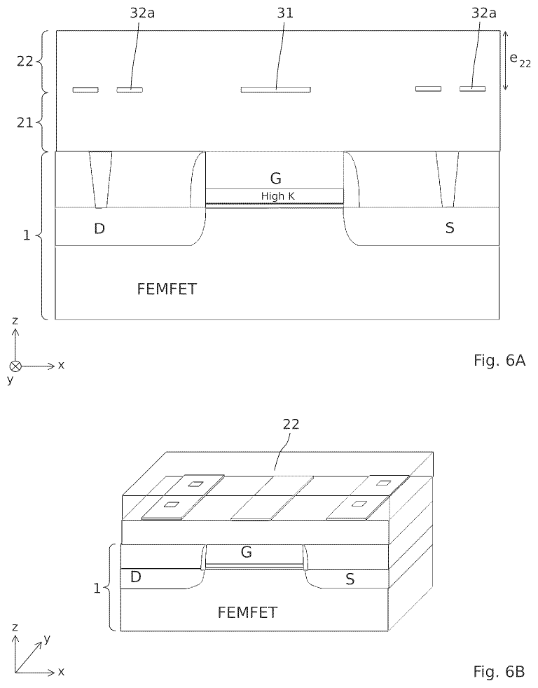

As illustrated in FIGS. 6A, 6B, after structuration of the ferroelectric layer 30a, a second metal layer 22, typically with the basis of a metal taken from among TaN, TIN, Al, Ru, Mo, is then formed on the first metal layer 21, and on the closed pattern 31 and the open patterns 32a. This metal layer 22 typically has a thickness e₂₂ of around a few tens of nanometres to a few hundreds of nanometres, for example, between 20 nm and 200 nm. The deposition of this metal layer 22 can, in particular, be done by PVD, CVD or ALD. After deposition, the second metal layer 22 can be planarised, for example, by CMP. The second metal layer 22 typically corresponds to a second metal level.

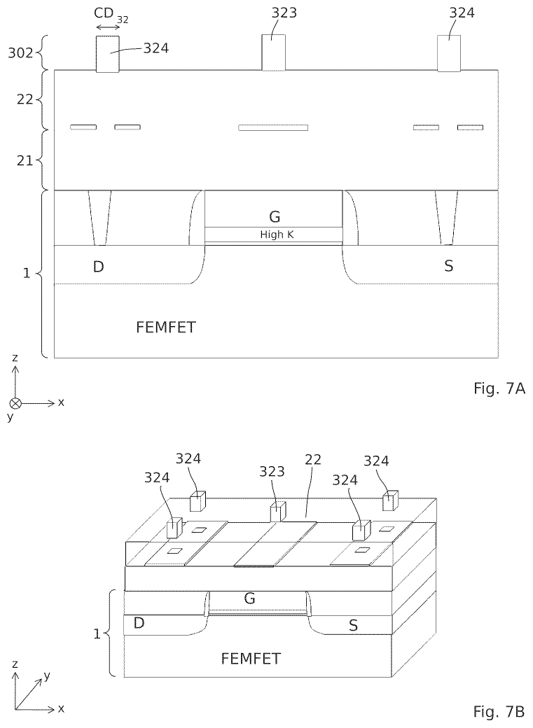

As illustrated in FIGS. 7A, 7B, a second etching mask 302 comprising via patterns 323, 324 is formed on the second metal layer 22. This second etching mask 302 is preferably organic layer-based, for example, in the form of a stack known as a “trilayer”, typically comprising an organic planarisation layer, an antireflection layer and a photosensitive resin layer.

The via patterns 324 of this second etching mask 302 are aligned in vertical alignment with the via openings 320 of the open patterns 32a. The via pattern 323 of this second etching mask 302 is aligned in vertical alignment with the closed pattern 31. The via patterns 324 typically have a dimension CD₃₂ along x, slightly greater, for example 10% greater, than the dimension CDₒₚₑₙ along x of the via openings 320 of the open patterns 32a. This facilitates the alignment of the patterns 324, 32a to one another. A certain tolerance on the alignment accuracy is thus obtained. The dimension CD₃₂ along x of the via patterns 324 is, for example, between 10 nm and 150 nm.

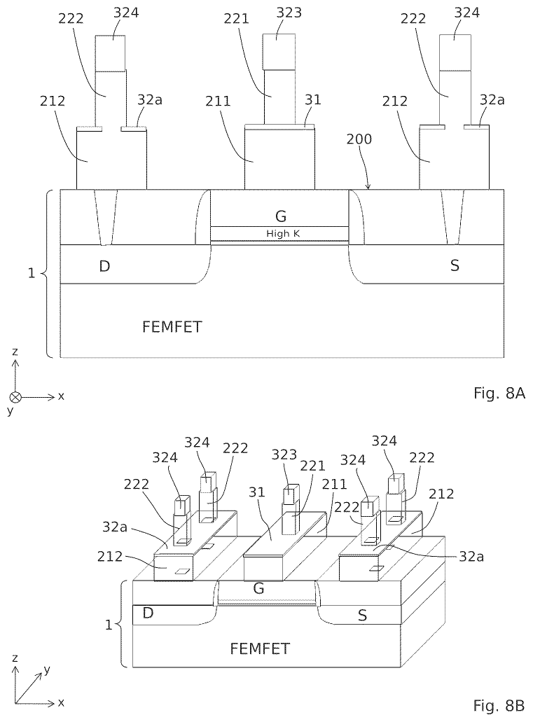

As illustrated in FIGS. 8A, 8B, the first and second metal layers 21, 22 are then etching over their entire thickness, along z, on either side of the via patterns 323, 324 and on either side of the open patterns 32a and of the closed pattern 31. The second metal layer 22 is first etched to form the vias 222, 221, then the first metal layer 21 is etched to form the lines 212, 211. The etchings of the first and second metal layers 21, 22 are preferably sequenced. According to an option, in particular, when the first and second metal layers 21, 22 are of an identical nature, the etchings of these metal layers 21, 22 are done in one single and same step, with the same etching chemistry.

The etchings are, in this case, chosen so as to selectively etch the first and second metals of the first and second metal layers 21, 22 with respect to the material of the ferroelectric layer (structured in the form of patterns 31, 32a). The ferroelectric layer is, in this case, advantageously used as an etching stop layer. In particular, the etching selectivity S_{21:30a}, i.e. the ratio between the etching speed of the metal of the first metal layer 21 over the etching speed of the material of the ferroelectric layer, is greater than or equal to 5:1, preferably greater than or equal to 10:1. The etchings can be with the basis of a CF₄/H₂-type chemistry.

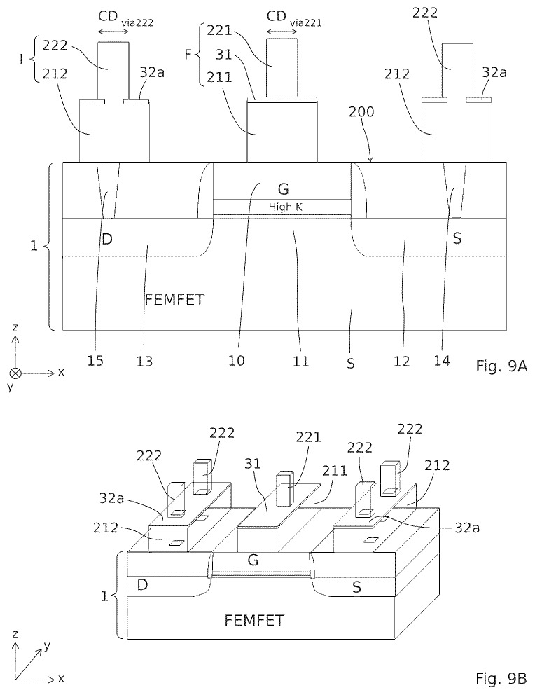

As illustrated in FIGS. 9A, 9B, after etching, the mask 302 is removed, for example, by oxygen-based plasma. Vias 222 having the dimension CDᵥᵢₐ₂₂₂ along x are obtained above the open patterns 32a. The dimension CDᵥᵢₐ₂₂₂ is substantially equal to the dimension CD₃₂ of the via patterns 324. A via 221 having the dimension CDᵥᵢₐ₂₂₁ along x is obtained above the closed pattern 31. An FeMFET device comprising interconnections I (212, 222) and a ferroelectric capacitor F (211, 31, 221) integrated in the interconnecting levels is thus advantageously obtained. The ferroelectric capacitor F comprises, in this case, a lower electrode formed by the line 211, an upper electrode formed by the via 221, and a ferroelectric separation layer 31 between the lower and upper electrodes. The ferroelectric capacitor F is, in this case, integrated between the first and second metal levels.

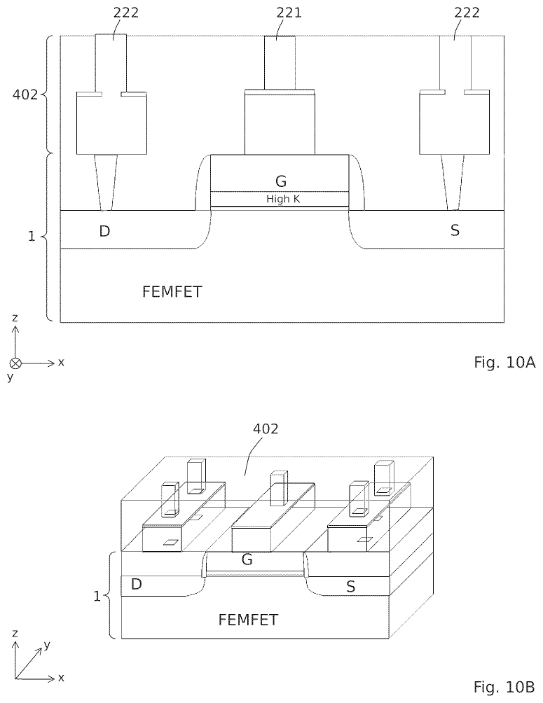

As illustrated in FIGS. 10A, 10B, the interconnections I and the ferroelectric capacitor F are then conventionally integrated in a dielectric matrix by deposition and planarisation of a dielectric layer 402, typically SiO₂-based.

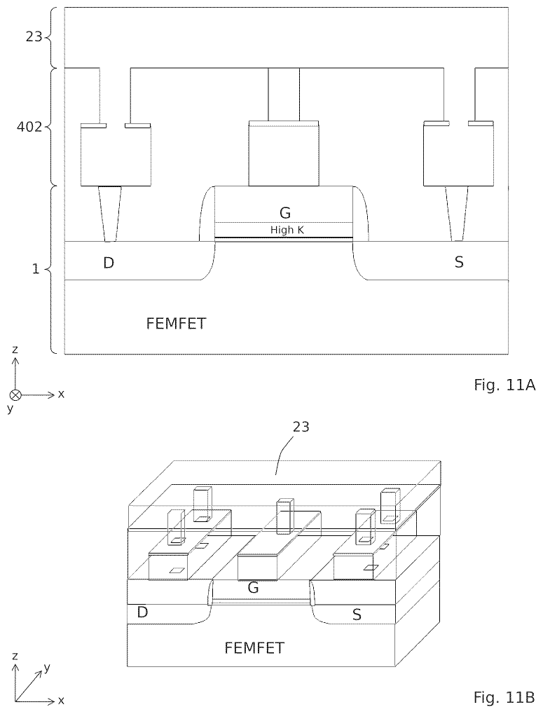

As illustrated in FIGS. 11A, 11B, a third metal layer 23, for example, TaN-, TIN-, Al-, Ru-, Mo-based, corresponding to a third metal level, can then be deposited flush on the layer 402 and the vias 221, 222.

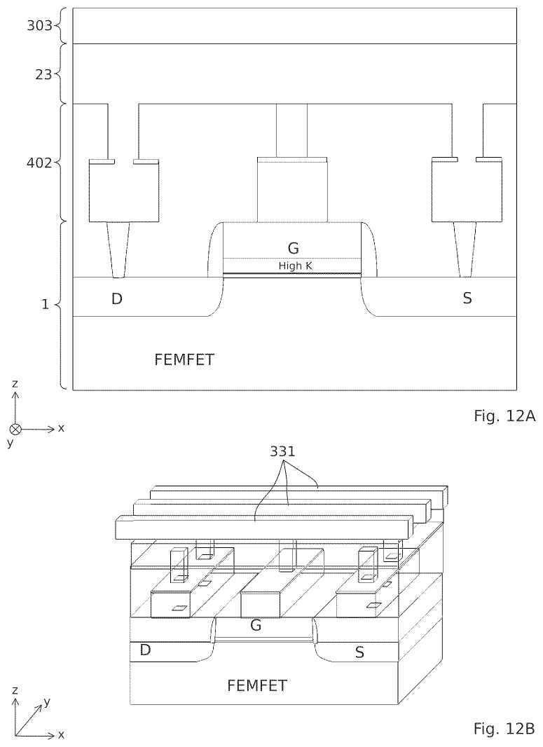

As illustrated in FIGS. 12A, 12B, a third mask 303 comprising, for example, line patterns 331 can be formed on the third metal layer 23.

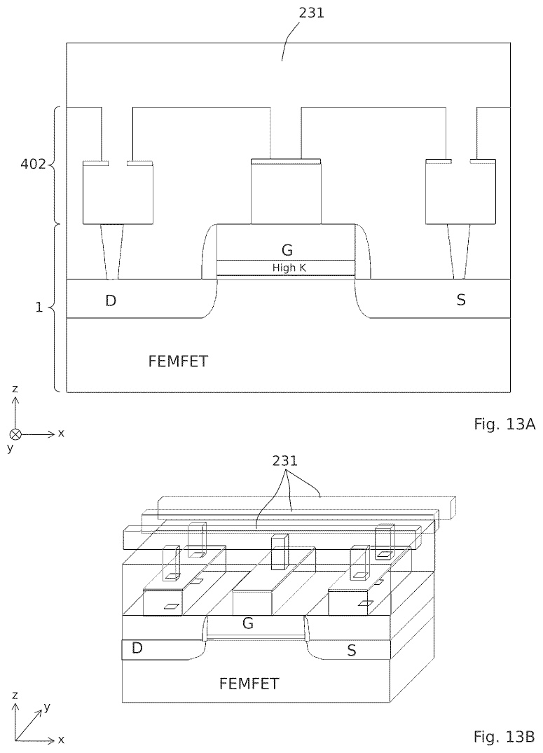

As illustrated in FIGS. 13A, 13B, the third metal layer 23 is then structured by etching through the mask 303. Lines 231 are thus formed in the third metal level. These lines 231 typically connect the vias 221, 222 of the second metal level.

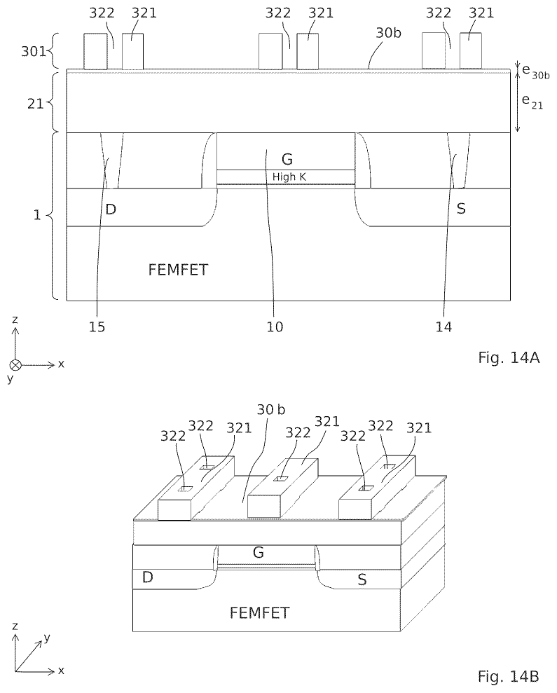

FIGS. 14A, 14B to 24A, 24B illustrate steps of manufacturing an FeMFET device according to a second embodiment of the invention. In this second embodiment, the ferroelectric capacitor of the FeMFET device is integrated in upper interconnecting levels. Only the steps and features, different from the first embodiment, are detailed below, the other steps and features being considered identical to those of the first embodiment.

As illustrated in FIGS. 14A, 14B, after formation of the first metal layer 21, an etching stop layer 30b is directly formed on the first metal layer 21. This etching stop layer 30b typically has a thickness e_{30b} of around a few nanometres, for example, between 2 nm and 15 nm. It is preferably with the basis of a dielectric material taken from among: SiO₂, TiO₂, HfO₂, HIN, ZrN, SiN, SiCN. The deposition of this etching stop layer 30b is preferably done by ALD. As above, an etching mask 301 is formed on the etching stop layer 30b. This etching mask 301 comprises, in this case, only open patterns 321 above vias 14, 15, and above the gate 10 of the transistor 1. The open patterns 321 comprise one or more openings 322, opening onto the underlying etching stop layer 30b.

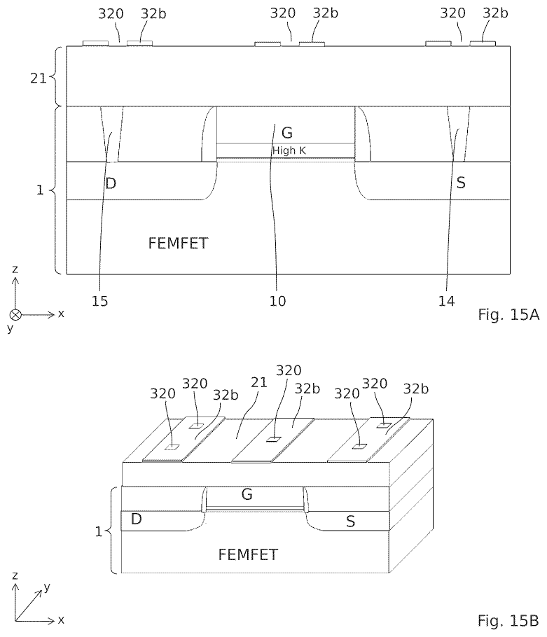

As illustrated in FIGS. 15A, 15B, the patterns 321 are transferred into the etching stop layer 30b by anisotropic etching along z of the etching stop layer 30b, in the presence of the mask 301. The open patterns 321 of the mask 301 form, after etching, the open patterns 32b comprising the via openings 320 in the etching stop layer 30b. The mask 301 is removed after etching, for example, by oxygen-based plasma.

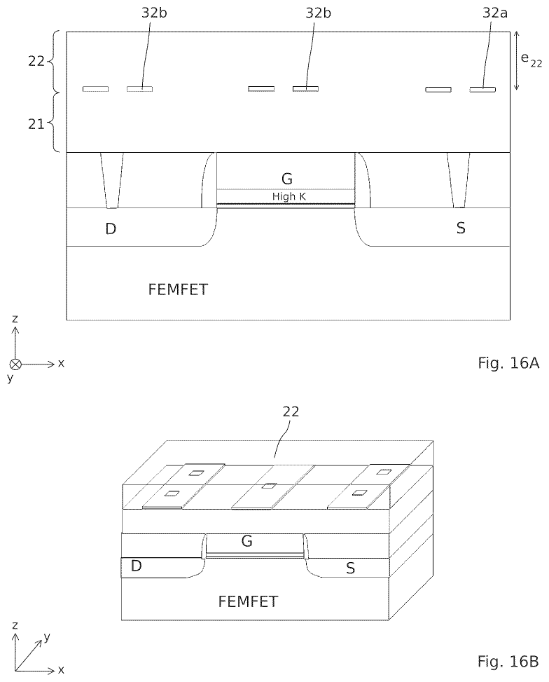

As illustrated in FIGS. 16A, 16B, after structuration of the etching stop layer 30b, a second metal layer 22, typically with the basis of a metal taken from among TaN, TIN, Al, Ru, Mo, is then formed on the first metal layer 21, and on the open patterns 32b. The second metal layer 22 typically corresponds to a second metal level.

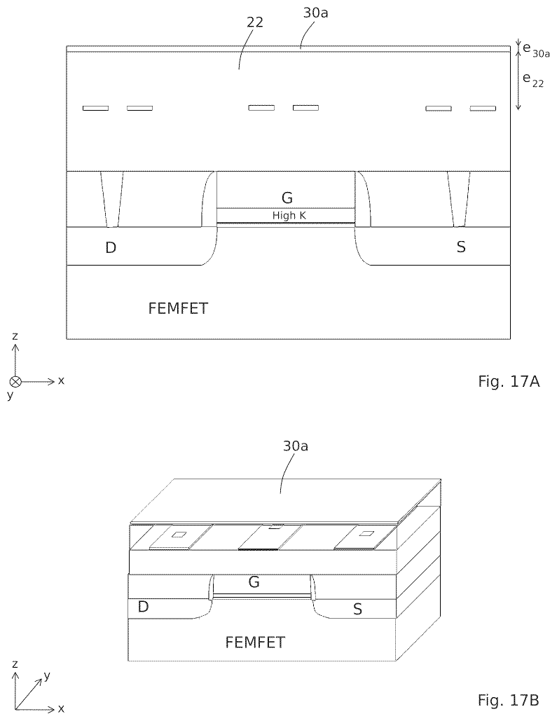

As illustrated in FIGS. 17A, 17B, a ferroelectric layer 30a is then directly formed on the second metal layer 22. This ferroelectric layer 30a typically has a thickness e₃₀ₐ of around a few nanometres, for example, between 2 nm and 15 nm. It is preferably with the basis of a material taken from among: HfₓZr₁₋ₓO₂, HfO₂. The deposition of this ferroelectric layer 30a is preferably done by ALD.

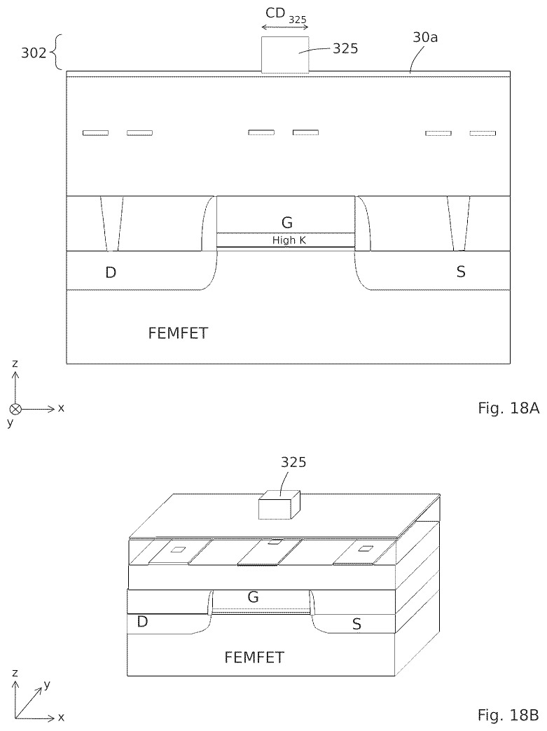

As illustrated in FIGS. 18A, 18B, a second etching mask 302 comprising an intermediate pattern 25 is formed on the ferroelectric layer 30a. This intermediate pattern 325 is aligned in vertical alignment with the via opening 320 of the open pattern 32b located above the gate 10 of the transistor. This intermediate pattern 325 typically has a dimension CD₃₂₅ along x, greater, for example, at least 20% greater, than the dimension CDₒₚₑₙ along x of the via opening 320 of the open pattern 32b. This facilitates the alignment of the patterns 325, 32b to one another. The sizing of the lower electrode of the capacitor and/or of the ferroelectric layer for separating the capacitor is also better controlled. The dimension CD₃₂₅ along x of the intermediate pattern 325 is, for example, between 10 nm and 200 nm.

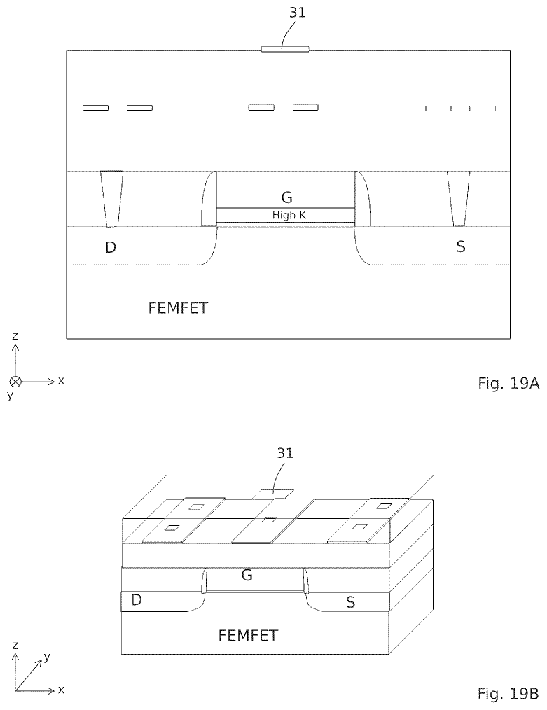

As illustrated in FIGS. 19A, 19B, the pattern 325 is transferred into the ferroelectric layer 30a by anisotropic etching along z of the ferroelectric layer 30a in the presence of the mask 302. The pattern 325 of the mask 302 forms, after etching, the closed pattern 31 in the ferroelectric layer 30a. The mask 302 is removed after etching, for example, by oxygen-based plasma.

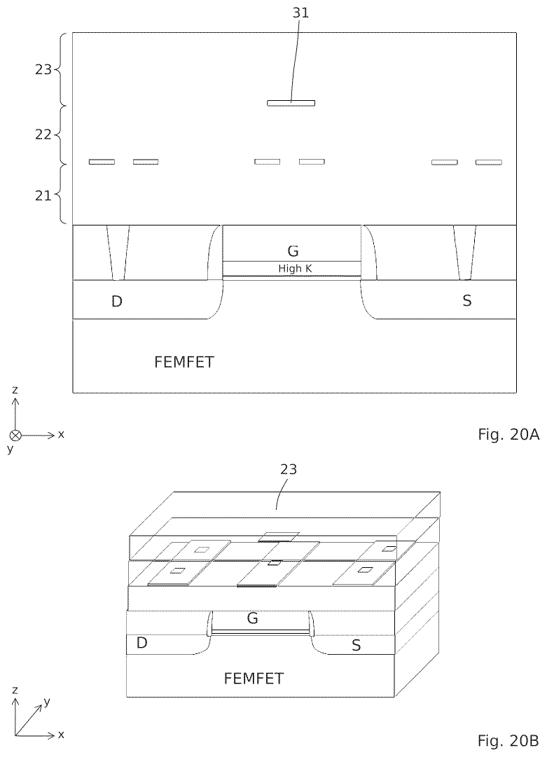

As illustrated in FIGS. 20A, 20B, after structuration of the ferroelectric layer 30a, a third metal layer 23, typically with the basis of a metal taken from among TaN, TIN, Al, Ru, Mo, is then formed on the second metal layer 22, and on the closed pattern 31. The third metal layer 23 typically corresponds to a third metal level.

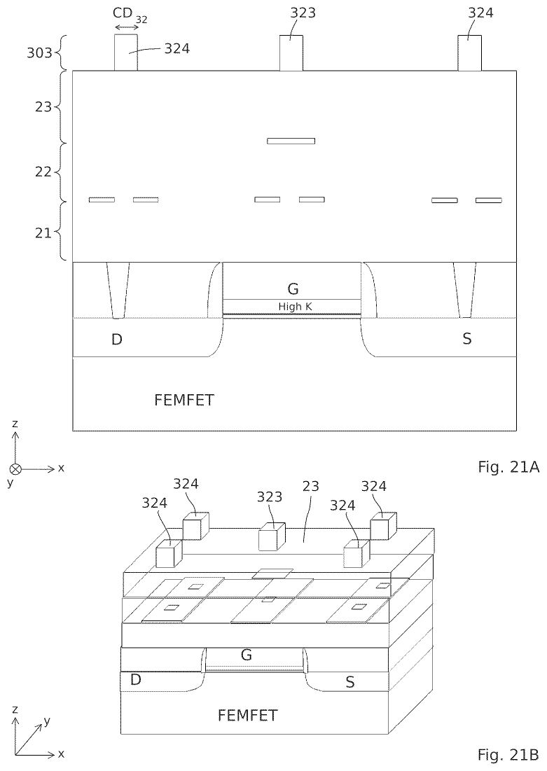

As illustrated in FIGS. 21A, 21B, a third etching mask 303 comprising via patterns 323, 324 is formed on the third metal layer 23. The via patterns 324 of this third etching mask 303 are aligned in vertical alignment with the via openings 320 of the open patterns 32b. The via pattern 323 of this third etching mask 303 is aligned in vertical alignment with the closed pattern 31. The via patterns 324 typically have a dimension CD₃₂ along x, slightly greater, for example, 10% greater, than the dimension CDₒₚₑₙ along x of the via openings 320 of the open patterns 32b. This facilitates the alignment of the patterns 324, 32a to one another. The dimension CD₃₂ along x of the via patterns 324 is, in this case, for example, between 8 nm and 150 nm.

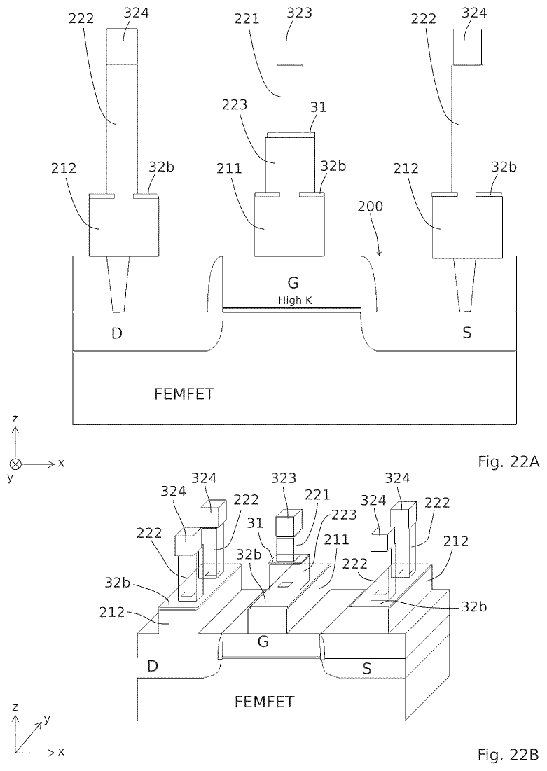

As illustrated in FIGS. 22A, 22B, the first, second and third metal layers 21, 22, 23 are then etching over their entire thickness, along z, on either side of the via patterns 323, 324 and on either side of the open patterns 32b and of the closed pattern 31. The third and second metal layers 23, 22 are first etched to form the vias 222, 221 and the terminal 223, then the first metal layer 21 is etched to form the lines 212, 211. The etchings of the first, second and third metal layers 21, 22, 23 are preferably sequenced. According to an option, in particular, when the first, second and third metal layers 21, 22, 23 are of an identical nature, the etchings of these metal layers 21, 22, 23 are done in one single and same step, with the same etching chemistry.

The etchings are, in this case, chosen so as to selectively etch the metals of the first, second and third metal layers 21, 22, 23 with respect to the material of the ferroelectric layer (structured in the form of the pattern 31), and with respect to the material of the etching stop layer (structured in the form of the patterns 32b). The etching stop layer and the ferroelectric layer are used as etching stop layers. In particular, the etching selectivity S_{22:31}, i.e. the ratio between the etching speed of the metal of the second metal layer 22 over the etching speed of the material of the ferroelectric layer, is greater than or equal to 5:1, preferably greater than or equal to 10:1. The etching selectivity S_{21:31}, i.e. the ratio between the etching speed of the metal of the first metal layer 21 over the etching speed of the material of the ferroelectric layer, is greater than or equal to 5:1, preferably greater than or equal to 10:1. The etching selectivity S_{21:30b}, i.e. the ratio between the etching speed of the metal of the first metal layer 21 over the etching speed of the material of the etching stop layer 30b, is greater than or equal to 5:1, preferably greater than or equal to 10:1. The etchings can be with the basis of a chlorinated chemistry. Alternatively, the etching(s) of the metal material(s) can be done in fluorinated or fluorocarbon chemistry. In this case, it is preferable to avoid SiN and SiO₂ as a dielectric material of the etching stop layer.

An FeMFET device comprising interconnections I (212, 222) and a ferroelectric capacitor F (211, 223, 31, 221) integrated in the interconnecting layers is thus advantageously obtained. The ferroelectric capacitor F comprises, in this case, a lower electrode formed by the line 211 and the terminal 223, an upper electrode formed by the via 221, and a ferroelectric separation layer 31 between the lower and upper electrodes. The ferroelectric capacitor F is, in this case, integrated between the second and third metal levels.

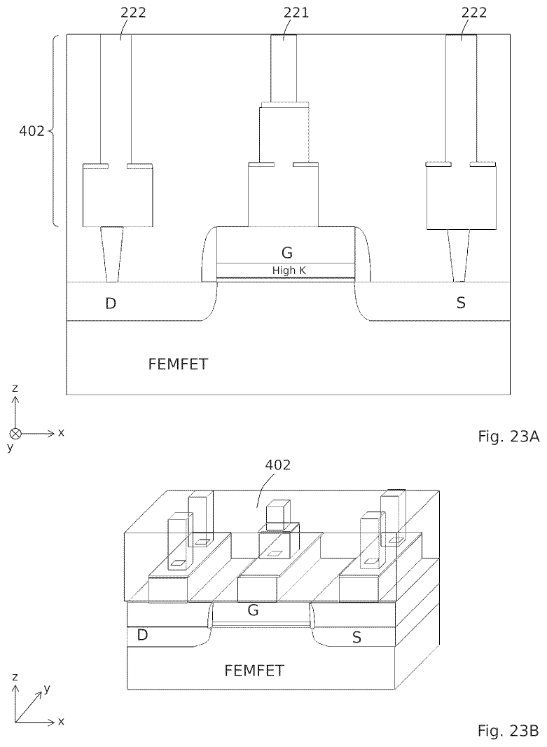

As illustrated in FIGS. 23A, 23B, after removal of the mask 303, the interconnections I and the ferroelectric capacitor F are then conventionally integrated in a dielectric matrix by deposition and planarisation of a dielectric layer 402, typically SiO₂-based.

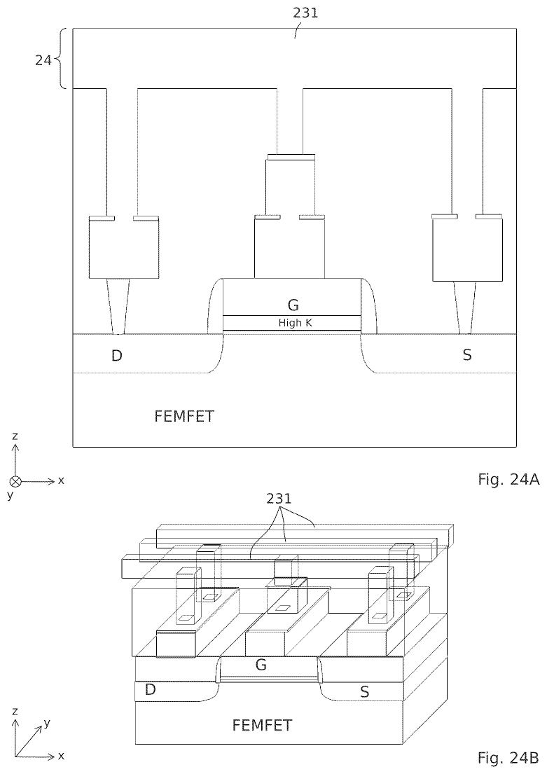

As illustrated in FIGS. 24A, 24B, a fourth metal layer 24, for example, TaN-, TiN-, Al-, Ru-, Mo-based, corresponding to a fourth metal level, can then be deposited flush on the layer 402 and the vias 221, 222. As above, the fourth metal layer 24 can be structured in the form of lines 231 connecting the vias 221, 222.

The invention is not limited to the embodiments described above. In particular, it can be considered to structure the ferroelectric layer and/or the etching stop layer indirectly, by forming etching masks of inverse polarity, then by performing a localised deposition of the materials of the ferroelectric layer and/or of the etching stop layer.

1. A FeMFET device, comprising, in a stack along a direction z:
a transistor comprising a gate surmounting a channel, a source, and a drain on either side of the channel;
an interconnection, connecting the source or the drain (13), comprising (a-i) a first metal line with a basis of a first metal, (a-ii) a first metal via with a basis of a second metal, connected to the first metal line, and (a-iii) an etching stop layer inserted between the first metal via and the first metal line, the etching stop layer comprising a via opening, such that the first metal via and the first metal line are connected through the via opening;
a ferroelectric capacitor connecting the gate, comprising (b-i) a second metal line with a basis of the first metal, and (b-ii) a second metal via with a basis of the second metal;
a first part of a ferroelectric layer inserted between the second via and the second metal line, the ferroelectric layer separating the second metal via and the second metal line.

2. The device of claim 1, wherein the etching stop layer inserted between the first metal via and the first metal line of the interconnection is ferroelectric.

3. The device of claim 1, wherein the interconnection comprises a first interconnection connecting the source and a second interconnection connecting the drain, and
wherein each of the first and second interconnections comprises an etching stop layer inserted between the first metal via and the first metal line of the interconnection.

4. The device of claim 1, wherein the first metal via of the interconnection connecting the source or the drain has a first critical dimension, CDᵥᵢₐ₂₂₂, taken along an axis x, greater than or equal to an opening dimension CDₒₚₑₙ of the via opening taken along the axis x.

5. The device of claim 1, wherein the second metal metal via of the ferroelectric capacitor has a second critical dimension, CDᵥᵢₐ₂₂₁, taken along an axis x, less than a ferroelectric layer dimension CD₃₁, taken along the axis x, of the ferroelectric layer separating the second via and the second metal line of the ferroelectric capacitor.

6. The device of claim 1, wherein the first and second metals comprise TaN, TIN, Al, Ru, and/or Mo.

7. A method for manufacturing the FeMFET device of claim 1, the method comprising:
forming a first metal layer on exposed faces of an upper surface of the transistor, the vias and the gate each having an exposed face, from among the exposed faces, at the upper surface;
forming, on the first metal layer, the ferroelectric layer with a basis of a ferroelectric material having, with respect to the first metal layer, a selectivity S_{21:30a} to the etching, greater than or equal to 5:1,
structuring the ferroelectric layer, through at least one first mask, so as to expose parts of the first metal layer and to preserve parts of the ferroelectric layer in the form of at least one closed pattern surmounting the gate of the transistor and at least one open pattern surmounting at least one of the vias connecting the source or the drain, the at least one open pattern comprising the via opening, opening onto the first metal layer underlying the ferroelectric layer;
forming a second metal layer exposed parts of the first metal layer and on the at least one closed pattern and the at least one open pattern;
forming, on the second metal layer, of a second mask defining at least one second via level in vertical alignment with the at least one closed pattern and in vertical alignment with the via opening of the at least one open pattern;
etching the second metal layer, so as to form the vias of a second level, by stopping on the ferroelectric layer acting as a first etching stop layer, and, etching the first metal layer on either side of the at least one closed pattern and the at least one open pattern, so as to form the first and the second metal lines as first-level lines, by stopping on an upper surface.

8. A method for manufacturing the FeMFET device of claim 1, the method comprising:
forming a first metal layer on exposed faces of an upper surface of the transistor, the vias and the gate each having an exposed face, from among the exposed faces, at the upper surface;
forming, on the first metal layer, of a second etching stop layer;
structuring the second etching stop layer, through at least one first mask, so as to expose parts of the first metal layer and to preserve parts of the second etching stop layer in the form of at least one open pattern surmounting the gate and at least one via connecting the source or the drain, the at least one open pattern comprising the via opening, opening onto the first metal layer, underlying the second etching stop layer;
forming a second metal layer on the exposed parts of the first metal layer and on the at least one open pattern;
forming, on the second metal layer, of a ferroelectric layer with a basis of a ferroelectric material having, with respect to the second metal layer, a selectivity $22:30a to etching, greater than or equal to 5:1;
structuring the ferroelectric layer, through at least one second mask, so as to expose parts of the second metal layer and to preserve parts of the ferroelectric layer in the form of at least one closed pattern surmounting the gate of the transistor;
forming a third metal layer on the exposed parts of the second metal layer and on the at least one closed pattern;
forming, on the third metal layer, of a third mask defining vias in vertical alignment with the at least one closed pattern and in vertical alignment with the at least one via opening of the at least one open pattern;
etching the third, second, and first metal layers, so as to form the vias, by stopping on the ferroelectric layer and on the etching stop layer, and to form lines by stopping on the upper surface.

9. The method of claim 7, wherein the ferroelectric layer comprise HfₓZr₁₋ₓO₂ and/or HfO₂.

10. The method of claim 7, wherein the ferroelectric layer has a thickness e₃₀ₐ in a range of from 2 to 15 nm.

11. The method of claim 7, wherein the vias of the second level surmounting the at least one closed pattern have a critical dimension CDᵥᵢₐ₂₂₁, taken along an axis x, less than a closed pattern dimension CD₁, taken along the axis x, of the at least one closed pattern.

12. The method of claim 7, wherein the vias of the second level surmounting the at least one open pattern have a critical dimension CDᵥᵢₐ₂₂₂, taken along an axis x, greater than or equal to an opening dimension CDₒₚₑₙ of the at least one via opening taken along the axis x.

13. The method of claim 7, wherein the first and second metal layers comprises an identical metal material.

14. The method of claim 7, wherein the etching of the second metal layer and the etching of the first metal layer are done by one single and same etching, during one single and same step.

15. The device of claim 1, wherein the first and second metals comprise TaN.

16. The device of claim 1, wherein the first and second metals comprise TiN.

17. The device of claim 1, wherein the first and second metals comprise Al.

18. The device of claim 1, wherein the first and second metals comprise Ru.

19. The device of claim 1, wherein the first and second metals comprise Mo.
